(19) United States
(12) Patent Application Publication
(10) Pub. No.: US 2007/0246721 A1
(43) Pub. Date: Oct. 25, 2007

(54) Semiconductor component having a curved mirror and method for producing a semiconductor component having a curved semiconductor body

(75) Inventors: Wolfgang Reill, Pentling (DE); Ulrich Steegmuller, Regensburg (DE); Tony Albrecht, Bad Abbach (DE); Wolfgang Schmid, Deuerling/Hillohe (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/209,558

(22) Filed: Aug. 23, 2005

(30) Foreign Application Priority Data
Aug. 23, 2004 (DE) 10 2004 040 762.2
Oct. 29, 2004 (DE) 10 2004 052 686.9

(51) Int. Cl. H01L 29/06; H01L 33/00; H01L 31/00; H01L 31/12; H01L 29/22; H01L 27/15

(52) U.S. Cl. 257/98; 257/13; 257/79; 257/84

(57) ABSTRACT

A semiconductor component having a semiconductor body, the semiconductor body comprising a curved mirror (3), which is monolithically integrated in the semiconductor body. A method for curving a semiconductor body is also disclosed.

### RELATED APPLICATIONS

This patent application claims the priority of German patent application nos. 10 2004 040 762.2 and 10 2004 052 686.9 filed Aug. 23, 2004 and Oct. 29, 2004, respectively, the disclosure content of which is hereby incorporated by reference.

### FIELD OF THE INVENTION

The invention relates to a semiconductor component having a curved mirror and to a method for producing a semiconductor component having a curved semiconductor body.

### BACKGROUND OF THE INVENTION

In the case of surface emitting semiconductor lasers with an external resonator and a vertical emission direction with respect to the surface of a semiconductor body of the laser, for example a VECSEL (Vertical External Cavity Surface Emitting Laser) or semiconductor disk laser, the external resonator is often formed by a planar Bragg mirror integrated in the semiconductor body of the semiconductor laser and a curved external dielectric mirror. Fundamental mode operation of the laser can be obtained by means of suitable curvature of the external mirror and a resonator length adapted thereto. The alignment of the curved mirror in three-dimensional space is often complicated, however, for an efficient laser activity, in particular in the fundamental mode, of the semiconductor laser with an external resonator. Furthermore, the production of curved optical elements is comparatively cost-intensive compared with planar optical elements.

### SUMMARY OF THE INVENTION

It is an object of the invention to provide a semiconductor component having a curved mirror which can be produced in a simplified and cost-effective manner.

Another object of the invention is to provide a method for producing a corresponding semiconductor body.

These and other objects are attained in accordance with one aspect of the present invention directed to a semiconductor component having a semiconductor body, the semiconductor body comprising a curved mirror, which is monolithically integrated in the semiconductor body.

The curvature of the mirror may advantageously be produced in a targeted manner after the production of the semiconductor body, for example by means of epitaxy on a suitable growth substrate. The semiconductor body can be produced in planar and uncurved fashion, and the curvature is produced after the growth of the semiconductor body.

By way of example, for the curvature of the mirror, a curvature element that induces the curvature or shapes the curvature is arranged on the semiconductor body. The semiconductor body and the monolithically integrated curved mirror can have a curvature of identical type. The curvature of the mirror may thus be produced through suitable curvature of the semiconductor body. In particular, the curved mirror may be embodied with a targeted and defined curvature.

A curved mirror can thus be produced cost-effectively and in a simple manner.

The mirror can be curved for the purpose of beam shaping and may have for example a convex or concave curvature, for instance elliptical curvature, spherical curvature or a different type of curvature suitable for beam shaping. Furthermore, the curved mirror preferably has a focus.

In one refinement of the invention, the curvature element is a, preferably metal-containing, stress layer that curves the semiconductor body by means of compressive or tensile stress induced by way of the stress layer.

In a further refinement of the invention, the curvature element is a shaping element having a partial region which is shaped in accordance with the desired curvature and onto which the semiconductor body or the mirror presses or which is pressed onto the semiconductor body and the semiconductor body is consequently curved in accordance with the shaping element.

In a further refinement of the invention, the curved mirror is a Bragg mirror. For this purpose, a plurality of semiconductor layer pairs for the Bragg mirror are preferably provided in the semiconductor body. The two semiconductor layers of a semiconductor layer pair can have a comparatively high refractive index difference and a correspondingly high individual pair reflectivity. The total reflectivity of the mirror can be set by way of the number of semiconductor layer pairs.

In a further refinement of the invention, the semiconductor body is arranged on a carrier, which preferably mechanically stabilizes and/or carries the semiconductor body, in particular prior to the curvature of the mirror. The carrier may be embodied in particular in planar fashion.

The semiconductor body furthermore can have at least one partial region that is curved for the curved mirror and at least one planar partial region. In this case, the curved partial region of the semiconductor body is surrounded by the planar partial region of the semiconductor body. A window can be arranged downstream of the curved partial region in the vertical direction, the carrier being thinned or cut out in said window. By way of example, the curved partial region overlaps, possibly completely overlaps, the window in the vertical direction.

A thinning or cutout makes it possible to reduce a mechanically stabilizing effect of the carrier for the semiconductor body in the region of the window, so that a curvature of the semiconductor body or of the mirror can be effected in a simplified manner. By cutting out the carrier, for instance, it is possible, in the region of the window, to reduce the adhesion of the semiconductor body on the carrier or the mechanically stabilizing effect of the carrier and the semiconductor body can be deformed in a simplified manner in the region of the window, in particular in a direction vertically with respect to a lateral main direction of extent of the carrier and/or of the semiconductor body. The curvature element can be arranged on that side of the semiconductor body which is remote from the carrier.

In a further refinement of the invention, the semiconductor body has an active zone intended for the generation of radiation. Consequently, the semiconductor component may be formed in particular as a radiation-emitting semiconductor component. The active zone can be curved in accordance with the curved mirror.

The radiation-emitting semiconductor component has a curved mirror that is monolithically integrated into the semiconductor body and is designed for beam shaping for a radiation generated in the active zone.

In a further refinement of the invention, the semiconductor component is a surface emitting semiconductor component. The main emission direction of radiation generated in the active zone runs essentially vertically with respect to the surface of the semiconductor body. The emission surface is that surface of the semiconductor body which is opposite to the curved mirror.

In a further refinement of the invention, the semiconductor component is provided for the generation of laser radiation by means of an external resonator. For the external resonator, an external mirror may be arranged downstream of the active zone. In this case, the external mirror may form the resonator end mirror and/or be provided as a mirror for coupling out radiation from the resonator. In particular, the external mirror may be embodied in essentially planar fashion since beam shaping is effected at the curved mirror of the semiconductor body. Fundamental mode operation of the semiconductor laser component with a planar external mirror is thus simplified.

Furthermore, it is possible to dispense with additional optical elements for beam shaping in the resonator, for instance lenses, or a folding of the resonator for reducing the beam waist of the radiation in the resonator. The resonator may be embodied, in particular, in unfolded fashion (with an unangled resonator axis).

The active zone may be electrically or optically pumped for the generation of radiation. In the resonator, a laser radiation field is thus built up by amplification of the radiation in the active zone.

In one refinement of the invention, the active zone for the generation of radiation is optically pumped by means of at least one pump radiation source, in particular a pump laser. A plurality of pump radiation sources may also be employed.

In one development of the invention, the pump radiation source and the semiconductor body are produced epitaxially on a common growth substrate. The pump radiation source can be formed as an edge emitting semiconductor laser. Forming the pump radiation source and semiconductor body in a monolithically integrated manner in this way results in a small spatial extent of the semiconductor component in conjunction with efficient optical pumping of the semiconductor component. The pump radiation source and semiconductor body can be arranged laterally next to one another and the active zone is optically pumped laterally during operation of the semiconductor component.

In a further refinement of the invention, the semiconductor body, in particular the active zone, contains at least III-V semiconductor material, for instance a material from the material systems InₓGa_{y}Al_{1-x-y}P, InₓGa_{y}Al_{1-x-y}As or InₓGa_{y}Al_{1-x-y}N, in each case where 0≦x≦1, 0≦y≦1 and x+y≦1. These materials are particularly suitable for efficient generation of radiation from the ultraviolet (e.g. InₓGa_{y}Al_{1-x-y}N) through the visible (e.g. InₓGa_{y}Al_{1-x-y}P or InₓGa_{y}Al_{1-x-y}N) to the infrared (e.g. InₓGa_{y}Al_{1-x-y}As) spectral region. Furthermore, the semiconductor body, in particular the active zone, may contain a semiconductor material from the material system InₓGa₁₋ₓAs_{y}P_{1-y}, where 0≦x≦1 and 0≦y≦1.

In a further refinement of the invention, the active zone is designed for the generation of radiation in the invisible, in particular infrared, spectral region.

In a further refinement of the invention, the active zone comprises a single or multiple quantum well structure. In the context of the application, the designation quantum well structure encompasses any structure in which charge carriers experience a quantization of their energy states as a result of confinement. In particular, the designation quantum well structure does not comprise any indication about the dimensionality of the quantization. It thus encompasses, inter alia, quantum wells, quantum wires and quantum dots and any combination of these structures.

In a further refinement of the invention, there is arranged in the external resonator a nonlinear optical element for frequency conversion, in particular for frequency multiplication, for instance for frequency doubling, of the radiation generated in the active zone. By way of example, a nonlinear crystal is suitable as the nonlinear optical element. The nonlinear optical element preferably converts radiation from the invisible spectral region into the visible spectral region.

On account of the curved mirror, it is possible, in a simplified manner, to obtain a small beam waist of the radiation in the nonlinear optical element. In particular, this enables the efficiency of the frequency conversion to be advantageously increased. Radiation in the resonator can be focused in the nonlinear optical element given a suitable design of the curved mirror. The power density of the radiation in the nonlinear optical element can be increased by means of focusing, thereby achieving an advantageous increase in the conversion efficiency of the frequency conversion in the nonlinear optical element.

The beam waist of the radiation in the resonator can advantageously be kept small by means of the curved mirror, in particular in combination with a plane uncurved external mirror, on the part of the external mirror, as a result of which the frequency conversion can be effected particularly efficiently in the vicinity of the external mirror. The nonlinear optical element may adjoin the external mirror or be arranged in direct proximity to the external mirror.

Another aspect of the present invention is directed to a method for producing a semiconductor component having a curved semiconductor body. Firstly, the semiconductor body is provided. Afterward, the semiconductor body is curved, whereupon the semiconductor component is completed.

In accordance with this method, a prefabricated semiconductor body, in particular a semiconductor body that has been grown epitaxially on a growth substrate, can advantageously be curved in a targeted manner. Furthermore, the curvature can be effected without impression of the semiconductor body, that is to say without removal of semiconductor material from the semiconductor body.

The semiconductor body can be curved in a vertical direction, perpendicular to a lateral main direction of extent of the semiconductor body.

The method can be used for producing a semiconductor component according to the invention, so that the features of the method described above and below may also relate to the semiconductor component, and vice versa.

In one refinement of the invention, the semiconductor body, during provision, is arranged on a carrier, which mechanically stabilizes and carries the semiconductor body. The carrier may comprise, by way of example, the growth substrate on which the semiconductor body was grown epitaxially.

However, the carrier may also differ from the growth substrate of the semiconductor body. In this case, the semiconductor body arranged on the growth substrate is arranged and/or fixed on a carrier for example on the part of the side opposite to the growth substrate, whereupon the growth substrate can be removed from the semiconductor body, for example by means of etching or a laser ablation method.

In a further refinement of the invention, a window is formed in the carrier prior to the curvature of the semiconductor body. For this purpose, the carrier may be correspondingly thinned or cut out for the window. The window preferably reaches from that side of the carrier which is remote from the semiconductor body as far as to the semiconductor body. For this purpose, the carrier is expediently cut out as far as the semiconductor body in the region of the window. By way of example, in order to form the window, the carrier is correspondingly patterned from its side remote from the semiconductor body. A suitable masking, for instance by means of a photoresist mask, in combination with etching, in particular wet-chemical etching is suitable for this purpose, by way of example.

If the carrier differs from the growth substrate, then the carrier may, if appropriate, also be correspondingly patterned before the semiconductor body is arranged on the carrier.

In a further refinement of the invention, a stress layer is applied to the semiconductor body as a curvature element, which stress layer curves the semiconductor body, in particular in a region arranged downstream of the window in the vertical direction, by way of stress, for instance compressive stress or tensile stress, induced by means of the stress layer. In the region of the window, the semiconductor body is particularly readily accessible to curvature since the adhesion to the carrier or the stabilizing effect of the carrier is reduced or absent in this region.

The curvature or the radius of curvature of the semiconductor body can be influenced by way of the layer thickness of the stress layer. The thicker the stress layer, the smaller, in general, the radius of curvature or the higher, in general, the curvature.

In a development of the invention, the stress layer contains a metal, for example Au, Pt, Cr, Ti, or an alloy, in particular an alloy with at least one of the abovementioned metals. Suitable thicknesses of the stress layer may range from 100 nm to 10 μm.

In a further refinement of the invention, the stress layer is sputtered or vapor-deposited onto the semiconductor body. The stress state, for instance compressively stressed or tensile-stressed, and thus the curvature, for instance concave or convex, of the semiconductor body may be set by way of the process parameters, for example by way of the granularity of particles to be applied onto the semiconductor body, e.g., by sputtering, for formation of the stress layer. Those particles may be from the above-mentioned stress layer metals.

In a sputtering deposition technique the granularity may be varied, for example, by varying the kinetic energy of ions that hit a solid target made of the material of the particles to be applied to the substrate. The ions eject particles from this target by colliding with the target. The ejected particles are the particles deposited on the substrate and their size depends on the kinetic energy of the ions colliding with the target. Sputtering is a method which is widely known and often used to apply a coating to a substrate. The kinetic energy of the ions can be varied by varying the voltage applied to the target, for example.

The influence of the particle size on the type of curvature can be readily determined by a person with ordinary skill in the art. The person ordinarily skilled in the art would, for this purpose, vary the size of the particles, e.g. by varying the voltage applied to the target, and measure the curvature of the semiconductor body resulting from the respective particle sizes. From this information, he would determine what particle size is suitable for a desired curvature.

A compressive stress is more likely to effect a convex curvature of the semiconductor body as seen from the opposite side of the semiconductor body from the stress layer, and a tensile stress is correspondingly more likely to effect a concave curvature of the semiconductor body.

In a further refinement of the invention, the stress layer is applied to the side of the semiconductor body opposite from the carrier.

In a further refinement, the curvature of the semiconductor body that is induced by the stress layer is mechanically stabilized by means of a stabilization layer that is subsequently applied to the stress layer. The stabilization layer may be applied to the stress layer galvanically, for example, and/or contains a metal, for example Cu, Au, Ag, or an alloy, in particular an alloy with at least one of said metals. The stabilization layer can be made thick compared with the stress layer and has, by way of example, a thickness of for example 100 μm or less, but the thickness is large enough that the curvature of the semiconductor body is stabilized. The stabilization layer may be curved in the region adjoining the semiconductor body in accordance with the curvature of the semiconductor body.

Furthermore, the stabilization layer advantageously has a high thermal conductivity, thus resulting in a good thermal linking of the semiconductor body via the stress and stabilization layers to a heatsink on which the stabilization layer may be arranged. The abovementioned metals, in particular Cu or Ag, and alloys based thereon have particularly high thermal conductivities and are also well suited to curvature stabilization.

In a further refinement of the invention, a shaping element is arranged downstream of the semiconductor body as a curvature element. The shaping element can have a region which is shaped in accordance with the desired curvature of the semiconductor body and onto which the semiconductor body presses itself, in particular in the region overlapping the window, or which is pressed onto the semiconductor body. The curvature of the semiconductor body is determined by the shaping of the region shaped in the shaping element. If appropriate, the curvature is produced by slight pressure exerted on the semiconductor body by means of the shaping element, which pressure does not damage the semiconductor body, and/or the curvature is stabilized by means of the shaping of the shaping element. The shaping element is expediently simultaneously formed as a heatsink.

In a further refinement of the invention, the semiconductor body is curved by means of a pressure exerted on the semiconductor body, preferably temporarily, by a pressure element. The curvature produced by the pressure can be stabilized by means of a stabilization layer, for instance a metal-containing layer, which can be applied to the semiconductor body while pressure is being exerted thereon, in such a way that the semiconductor body is advantageously also curved after the process of exerting pressure has ended. The pressure can be exerted on the semiconductor body by means of the pressure element as gas pressure, for instance by means of a pump or a fan, or as hydrodynamic pressure, for instance by means of a liquid. The pressure is preferably exerted on the semiconductor body in such a way that the semiconductor body is curved in a partial region, which in particular overlaps the window of the carrier, but a remaining partial region of the semiconductor body continues to have a planar profile.

In a further refinement, a plurality of semiconductor components having a curved semiconductor body can be produced simultaneously in the wafer assembly by means of the method according to the invention. By way of example, for this purpose, a semiconductor layer sequence which is arranged on a carrier layer and is provided for forming a plurality of semiconductor bodies, possibly of identical type, is curved in a plurality of partial regions in accordance with the method described above.

If the semiconductor layer sequence is formed for semiconductor bodies for semiconductor laser components with an external resonator, then a, preferably planar, external mirror layer provided for a plurality of external mirrors may be arranged downstream of the assembly. The mirror layer may be aligned in the vertical direction relative to the semiconductor layer sequence as early as in the assembly.

Individual semiconductor components can be obtained from the assembly by singulation.

### BRIEF DESCRIPTION OF THE DRAWINGS

Intermediate steps of a first exemplary embodiment of a method according to the invention are illustrated schematically by the sectional views shown in FIGS. 1, 2 and 3.

Intermediate steps of a second exemplary embodiment of a method according to the invention are illustrated schematically by the sectional views shown in FIGS. 1, 2, 4A and 4B.

FIG. 5 shows a sectional view of a first exemplary embodiment of a semiconductor component according to the invention.

FIG. 6 shows a sectional view of a second exemplary embodiment of a semiconductor component according to the invention.

FIG. 7 shows a sectional view of a third exemplary embodiment of a semiconductor component according to the invention.

FIG. 8 shows a sectional view of a fourth exemplary embodiment of a semiconductor component according to the invention.

### DETAILED DESCRIPTION OF THE DRAWINGS

Elements that are identical, of identical type or act identically are provided with the same reference symbols in the figures.

FIGS. 1 to 3 schematically illustrate a first exemplary embodiment of a method according to the invention on the basis of intermediate steps shown in the figures.

Firstly, as shown in FIG. 1, provision is made of a semiconductor layer sequence 100 arranged on a carrier layer 400, said semiconductor layer sequence comprising an active zone 2 provided for the generation of radiation and a mirror structure 3. The mirror structure 3 is integrated with the active zone 2, in particular monolithically in the semiconductor layer sequence.

The carrier layer 400 is provided for example by the growth substrate on which the semiconductor layer sequence was grown epitaxially, or may comprise the growth substrate. If appropriate, however, the carrier substrate may also differ from the growth substrate. The semiconductor layer sequence 100 has a main direction of extent along the carrier layer 400 and is formed essentially in uncurved and planar fashion, as is customary according to a conventional epitaxy method.

The mirror structure 3 is formed in accordance with a Bragg mirror and for this purpose comprises a plurality of semiconductor layer pairs which in each case have a first layer 31 and a second layer 32, whose refractive index difference is comparatively high, and are embodied as λ/4 layers for radiation generated in the active zone 2. The reflectivity of the Bragg mirror is determined by way of the number of semiconductor layer pairs.

By way of example, the active zone 2 is designed for the generation of radiation in the infrared spectral region. For this purpose, the semiconductor layer sequence is preferably based on the III-V semiconductor material system InₓGa_{y}Al_{1-x-y}As, where 0≦x≦1, 0≦y≦1 and x+y≦1. In this case GaAs is particularly suitable as the carrier layer 400 or growth substrate. In this case, the semiconductor layer pairs comprise for example an AlGaAs layer as first layer 31 and a GaAs layer as second layer 32.

The active zone may be designed for example as a single or multiple quantum well structure. Structures of this type are particularly suitable for the efficient generation of radiation in the active zone.

The semiconductor layer sequence 100 of the wafer assembly comprising the semiconductor layer sequence and the carrier layer 400 as illustrated in FIG. 1 is intended for the production of a plurality of semiconductor bodies that emerge from partial regions of the semiconductor layer sequence.

The carrier layer 400 is subsequently patterned, preferably from the side opposite to the semiconductor layer sequence, in such a way that a plurality of windows 5 reaching from that side of the carrier layer which is opposite to the semiconductor layer sequence as far as to the semiconductor layer sequence are formed in the carrier layer. The resulting structure is illustrated schematically in FIG. 2 on the basis of a sectional view. An illustration of the individual elements of the semiconductor layer sequence 100 (e.g. mirror structure and active zone) is dispensed with in FIG. 2 and the subsequent figures for reasons of clarity.

The windows 5 may be patterned for example by means of suitable masking and etching from the side opposite to the semiconductor layer sequence into the carrier layer. By way of example, photolithographic methods using a photoresist mask, wet-chemical etching of the carrier layer and subsequent removal of the photoresist mask are suitable for this.

After the intermediate step shown in FIG. 2, in a first exemplary embodiment of the method according to the invention in accordance with FIG. 3, the partial regions of the semiconductor layer sequence 100 which overlap the windows 5 are curved in a targeted manner by means of a shaping element 600, onto which the semiconductor layer sequence presses and which has a plurality of curved partial regions 601 preformed in accordance with the desired curvature of the semiconductor layer sequence. In this case, the curvature is determined by the configuration of the shaping element 600.

The shaping element 600 is preferably pressed onto the semiconductor layer sequence 100 with such a low force that the semiconductor layer sequence curves in partial regions 601, but the semiconductor layer sequence, in particular the active zone, remains functional for generation of radiation. Outside the preformed partial regions 601, the semiconductor layer sequence preferably continues to have a planar profile.

The shaping element is expediently simultaneously formed as a heatsink and contains for example a metal or an alloy, for instance CuWo, so that heat arising during the generation of radiation in the active zone can be dissipated in a simplified manner. Afterward, singulation into semiconductor components may be effected along lines 7, said semiconductor components in each case comprising a curved mirror, which is monolithically integrated in a semiconductor body emerging from the semiconductor layer sequence during singulation, said curved mirror emerging from the mirror structure during singulation. The singulation may be effected for example by means of sawing or laser separation.

In a second exemplary embodiment of a method according to the invention for producing a semiconductor component having a curved semiconductor body, which is illustrated schematically in FIGS. 1, 2, 4A and 4B, firstly the procedure is in accordance with FIG. 1 and FIG. 2 and as already explained in connection with these figures. Afterward, a stress layer 800 is applied, preferably in whole-area fashion, to that side of the semiconductor layer sequence 100 which is opposite to the carrier layer 400. The stress layer is preferably vapor-deposited or sputtered onto the semiconductor layer sequence 100 and contains Au, for example.

The stress layer induces a stress in the regions of the semiconductor layer sequence which overlap the windows 5 since, in these partial regions, the semiconductor layer sequence is not mechanically stabilized by adhesion to the carrier layer and is thus accessible to deformation in a simplified manner.

The stress of the semiconductor body and, by this means, the curvature—curved convexly or, as illustrated, curved concavely as seen from the window or that side of the semiconductor layer sequence which is opposite to the stress layer—can be influenced by way of the process parameters during the application of the stress layer. A concave curvature as illustrated in FIG. 4A may be obtained by means of a tensile stress generated in a controlled manner by the stress layer.

The radius of curvature of the partial regions 101 of the semiconductor layer sequence 100 that are curved in the region of the windows 5 can be influenced by way of the thickness of the stress layer 800, the radius of curvature generally decreasing as the thickness increases. By way of example, the semiconductor layer sequence may be curved in such a way that a curved, in particular concave, mirror having a focal length of 2 to 20 mm is formed in the curved partial regions.

The curved partial regions of the semiconductor layer sequence are preferably curved in an identical fashion.

The structure that results after the application of the stress layer 800 is illustrated on the basis of a schematic sectional view in FIG. 4A.

In a further method step, as shown in FIG. 4B, the curvature may be stabilized by means of a stabilization layer 900 that is subsequently applied to the stress layer. The stabilization layer preferably contains a metal, for instance Cu, has a high thermal conductivity and/or is applied to the metal-containing stress layer 800 galvanically.

Afterward, singulation into semiconductor components may be effected along the lines 7, said semiconductor components in each case having a semiconductor body having a curved Bragg mirror which is monolithically integrated into the semiconductor body.

By means of the methods explained with reference to FIGS. 1 to 4B, the prefabricated semiconductor layer sequence or an individual semiconductor body can be curved in a cost-effective, targeted and defined manner.

As an alternative or in addition to the above methods, the semiconductor layer sequence may be curved by means of a pressure exerted on the semiconductor layer sequence by a pressure element. By way of example, for this purpose, an excess pressure or negative pressure is exerted on the semiconductor layer sequence by means of a fan or a pump from that side of the semiconductor layer sequence which is opposite to the carrier layer or through the windows in the carrier layer, said semiconductor layer sequence curving in a correspondingly targeted manner on account of the pressure exerted, in particular in the partial regions that overlap the windows.

By way of example, for this purpose, each partial region to be curved may be assigned a channel of the pump or fan, so that the pressure, in a manner delimited locally and in targeted fashion by means of the channels, is exerted on the partial regions of the semiconductor layer sequence that are to be curved, and the partial regions that are not be curved experience only a correspondingly lower pressure and thus preferably continue to have a planar profile.

Pressure may also be exerted on the semiconductor layer sequence in a spatially resolved manner if appropriate from that side of the carrier layer which is opposite to the semiconductor layer sequence through the windows of the carrier layer. The windows preferably serve as “channels” on account of the high stability of the carrier layer, as a result of which the semiconductor layer sequence is curved in the partial regions that overlap the windows. In particular, it is thus advantageously possible for a uniform, location-independent pressure to be exerted on the carrier layer, which pressure curves the semiconductor layer sequence in the partial regions that overlap the windows and thus in a spatially resolved manner, the remaining partial regions preferably continuing to have a planar profile on account of the comparatively high stability of the carrier layer counteracting the uniform pressure.

If appropriate, a uniform pressure may also be exerted on the semiconductor layer sequence from that side of the semiconductor layer sequence which is opposite to the carrier layer, the semiconductor layer sequence curving in the partial regions that overlap the windows on account of the reduced adhesion to the carrier layer in the region of the windows, but preferably continuing to have a planar profile in the remaining partial regions on account of the stabilizing adhesion—counteracting the pressure—to the carrier layer.

The curvature produced by the pressure may be stabilized by means of a stabilization layer applied to the semiconductor layer sequence while pressure is being exerted, for instance similar to a comparatively thick metal-containing stabilization layer of the type mentioned above, so that the semiconductor layer sequence is also curved at least in partial regions after the process of exerting pressure has ended. The stabilization layer may be for example vapor-deposited or sputtered onto the semiconductor layer sequence. The greater the pressure, the greater, in general, the curvature. The pressure may be exerted on the semiconductor layer sequence, if appropriate, in particular in spatially resolved fashion or uniformly, by means of a liquid which preferably comes directly into contact with the semiconductor layer sequence for the purpose of exerting pressure.

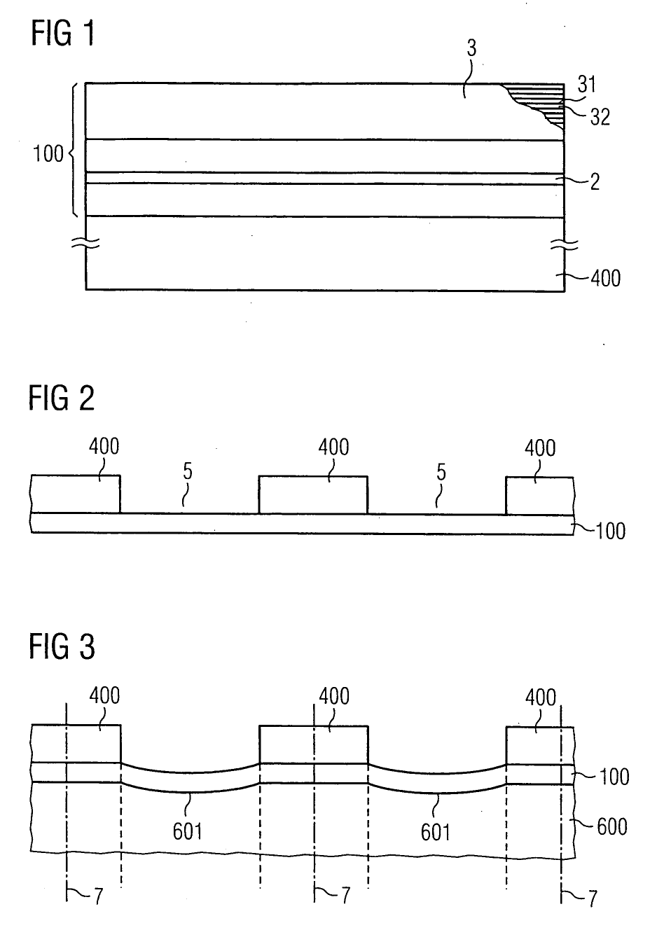

FIG. 5 illustrates a first exemplary embodiment of a semiconductor component according to the invention on the basis of a schematic sectional view. By way of example, a semiconductor component in accordance with FIG. 5 may be produced using the method according to FIGS. 1, 2, 4A and 4B.

A semiconductor body 1 having an active zone (not illustrated) intended for the generation of radiation is arranged on a carrier 4, which is cut out in the region of a window 5. A Bragg mirror (not illustrated) is monolithically integrated in the semiconductor body on that side of the active zone which is remote from the carrier 4, said Bragg mirror being curved in a targeted manner in the region that overlaps the window 5. A stress layer 8 is arranged on the side of the Bragg mirror which is remote from the carrier 4. This produces, for example, a tensile stress that brings about the curvature at the semiconductor body, which results in a concave curvature—as seen from the window—of the semiconductor body in the region that overlaps the window.

By means of the stabilization layer 9, the curvature or the radius of curvature of the semiconductor body is stabilized and the semiconductor body is preferably thermally conductively connected to an external heatsink 10, for instance containing Cu, on which the stabilization layer is preferably arranged. The structure with the carrier, the semiconductor body, the stress layer and the stabilization layer may emerge for example during singulation from the structure shown in FIG. 4B.

The semiconductor body 1 has a curved partial region in the region of the window and has an essentially planar profile with respect to the surface of the carrier outside the curved partial region and laterally adjoining the latter.

Arranged downstream of the semiconductor body 1 is an external mirror 11, which is embodied in planar fashion in this exemplary embodiment, and, together with the Bragg mirror integrated in the semiconductor body 1, forms an external, preferably straight or unfolded, resonator for a radiation 13 generated in the active zone.

A radiation field which can be amplified by stimulated emission in the active zone to form laser radiation can build up between the two mirrors.

For the generation of radiation, the active zone is optically pumped by means of an external pump laser which generates a pump radiation 12 having a wavelength that is less than the radiation to be generated in the active zone. The pump radiation 12 is absorbed in the active zone and re-emitted as radiation 13 having a greater wavelength, for instance in the infrared. Radiation can be coupled out from the resonator on the part of the external mirror 11 that is preferably formed as a coupling-out mirror.

In this exemplary embodiment, the semiconductor component is formed as a semiconductor laser component with an external resonator (VECSEL or semiconductor disk laser). The beam shaping of the radiation in the resonator is effected essentially exclusively by means of the curved Bragg mirror in the semiconductor body. The semiconductor laser component can preferably be operated in the fundamental mode, for instance the Gaussian fundamental mode TEM₀₀. A focal length of the curved Bragg mirror lies between 2 and 20 mm, by way of example.

More extensive optical elements, in particular curved and thus comparatively cost-intensive optical elements, for beam shaping in the resonator can advantageously be dispensed with.

In order to produce semiconductor laser components of this type, it is possible, by way of example in the wafer assembly in accordance with FIGS. 4A and 4B, to produce a targeted curvature of the semiconductor body or of the semiconductor layers in partial regions that are provided for forming semiconductor bodies.

An external mirror layer, which is provided for forming a plurality of external mirrors and is preferably embodied in plane fashion, may be arranged downstream of the structure from FIG. 4B. The vertical distance with respect to the semiconductor body or the active zone and mirror layer can be set by means of spacers arranged for example on that side of the carrier layer which is opposite to the semiconductor layer sequence. The alignment of the plane external mirror relative to the active zone can thus advantageously be carried out in a simple manner and as early as in the wafer assembly.

Furthermore, by means of a curvature of the Bragg mirror integrated in the semiconductor body, it is possible to realize short resonators, in particular having a resonator length of less than 5 mm, for efficient laser operation in a simplified manner. In pulsed operation, high modulation frequencies—the temporal sequential frequency of pulses—of more than 50 MHz thus become accessible in a simplified manner since shortened resonator lengths make it easier to attain higher modulation frequencies.

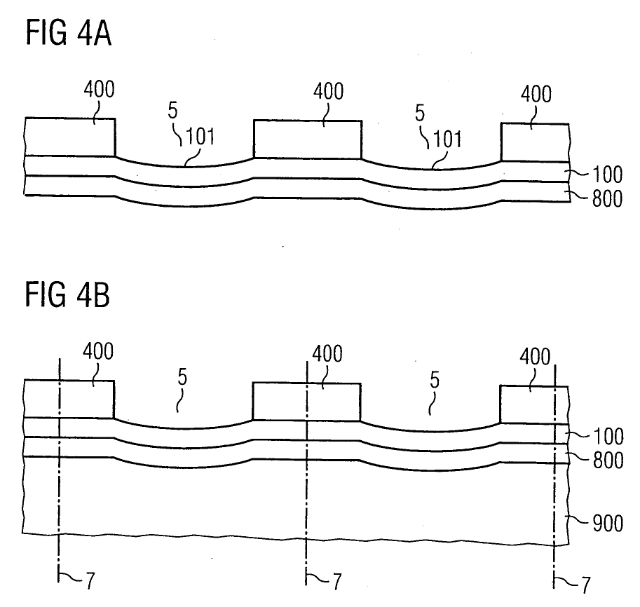

FIG. 6 schematically illustrates a second exemplary embodiment of a semiconductor component according to the invention on the basis of a sectional view. The component shown in FIG. 6 essentially corresponds to that shown in FIG. 5. In contrast to FIG. 5, the active zone in FIG. 6 is not optically pumped by means of an external pump laser. Rather, the pump radiation source and the semiconductor body are produced on a common substrate, preferably epitaxially on a growth substrate.

For this purpose, by way of example, firstly a semiconductor layer sequence for the surface emitting semiconductor body is grown on a substrate, then partial regions of the semiconductor layer sequence are removed and the pump radiation source can be produced epitaxially on the substrate in the removed regions. The pump radiation and the semiconductor body may in particular be monolithically integrated. In this case, an edge emitting semiconductor laser is particularly suitable as the pump radiation source.

The pump radiation 12 couples into the active zone of the semiconductor body 1 for example from a plurality of pump radiation sources 120 from the lateral direction. The semiconductor body may, as illustrated, be arranged between two pump radiation sources or overlap a resonator of a pump radiation source 120. A resonator of the pump radiation source may be laterally delimited by a first side area 14 and a second side area 15, for example, which may be formed as mirror areas. Mirror areas of this type may emerge from the structures produced for the pump radiation sources during singulation, for example, for instance by means of suitable cleavage in the wafer assembly.

In this exemplary embodiment, the active zone of the semiconductor body is optically pumped laterally by a monolithically integrated edge emitting pump laser.

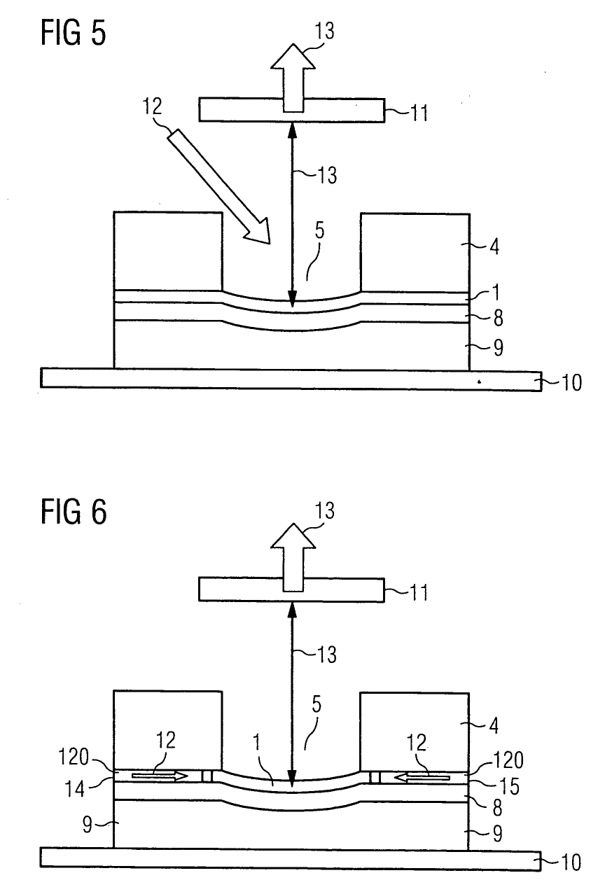

FIG. 7 schematically illustrates a third exemplary embodiment of a semiconductor component according to the invention on the basis of a sectional view. The semiconductor component essentially corresponds to a component shown in FIG. 5 or FIG. 6. Accordingly, the active zone may be optically pumped laterally in monolithically integrated fashion or externally.

In contrast to the previous exemplary embodiments, there is arranged in the external resonator a nonlinear optical element 16, for instance a nonlinear optical crystal, such as BiBo (bismuth triborate), for frequency conversion. Radiation generated and amplified in the active zone by optical pumping or induced emission can be doubled in frequency (SHG: Second Harmonic Generation) in the nonlinear optical element 16, so that visible, for instance green or blue, radiation results for example from invisible, for instance infrared, radiation.

Frequency-converted radiation 160 can be coupled out from the resonator via the external mirror. For this purpose, the external mirror is preferably designed to be highly transmissive for the frequency-converted radiation 160 and highly reflective for the non-converted radiation. In order to increase the efficiency of the frequency conversion or to keep the resonator losses low, the nonlinear optical element may be provided with antireflection coatings on the radiation entry and/or exit side.

On account of the curved mirror in the semiconductor body and the plane external mirror, an advantageously small beam waist, as is indicated on the basis of lines 17 in FIG. 7, can be obtained by means of a straight, unfolded resonator on the part of the external mirror. A folding, for instance in accordance with a Z or W resonator, can advantageously be dispensed with in the same way as curved optical elements. Measures of this type may increase resonator-internal losses, for example by way of scattering, diffraction, reflection or absorption losses, and are comparatively cost-intensive.

The nonlinear optical element 16 may be arranged in particular at the focus of the curved mirror, so that the efficiency of the frequency conversion is increased on account of the power density that is increased by means of focusing in the nonlinear optical element.

Furthermore, the active zone is arranged in the resonator preferably in accordance with an RPG structure (RPG: Resonant Periodic Gain). This means that the active zone, for instance the quantum well structure thereof, is arranged in the resonator in such a way that it overlaps an antinode of a standing wave that forms in the resonator, so that the amplification in the active zone can be effected particularly efficiently.

In an exemplary dimensioning of the resonator, the resonator length is approximately 10 mm and the distance between the deepest point of the curved mirror and the carrier is 1 μm.

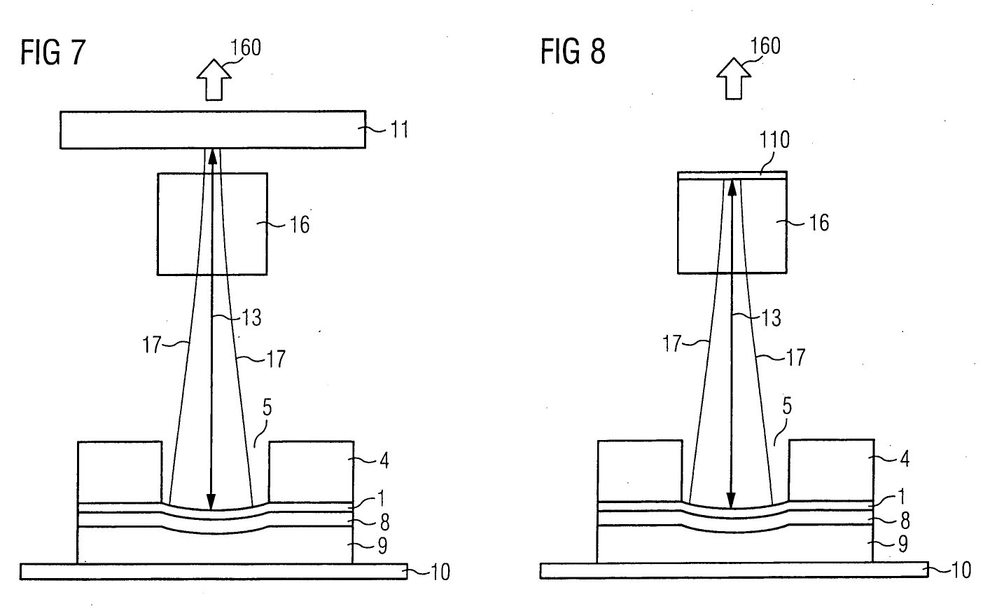

FIG. 8 schematically illustrates a fourth exemplary embodiment of a semiconductor component according to the invention on the basis of a sectional view. The exemplary embodiment in FIG. 8 essentially corresponds to that shown in FIG. 7; in contrast thereto, a separate external mirror 11 is dispensed with. Rather, the mirror 11 is in this case formed as a coating on the nonlinear optical element, in particular that side of the latter which is remote from the active zone. As a result, it is possible to achieve a more extensive reduction of the beam waist in the nonlinear optical element. The coating 110 on the part of the light exit side from the resonator is preferably highly reflective for the wavelength of the radiation 13 generated in the active zone, and preferably highly transmissive for the frequency-converted radiation 160.

The scope of protection of the invention is not limited to the examples given hereinabove. The invention is embodied in each novel characteristic and each combination of characteristics, which particularly includes every combination of any features which are stated in the claims, even if this feature or this combination of features is not explicitly stated in the claims or in the examples.

We claim:

1. A semiconductor component having a semiconductor body (1), the semiconductor body comprising a curved mirror (3), which is monolithically integrated in the semiconductor body.

2. The semiconductor component as claimed in claim 1,
wherein
the semiconductor body (1) and the curved mirror (3) have a curvature of identical type.

3. The semiconductor component as claimed in claim 1,
wherein
the curved mirror (3) is a Bragg mirror.

4. The semiconductor component as claimed in claim 1,
wherein
the semiconductor body (1) is arranged on a carrier (4).

5. The semiconductor body as claimed in claim 4,
wherein
the carrier (4) is planar.

6. The semiconductor component as claimed in claim 1,
wherein
the semiconductor body (1) has at least one partial region that is curved for the curved mirror (3) and at least one planar partial region.

7. The semiconductor component as claimed in claim 6,
wherein
a window (5) is arranged downstream of the curved partial region in the vertical direction, the carrier (4) being thinned or cut out in said window.

8. The semiconductor component as claimed in claim 7,
wherein
the curved partial region overlaps the window (5) in the vertical direction.

9. The semiconductor component as claimed in claim 1,
wherein
a curvature element (600, 800, 8) that induces the curvature or shapes the curvature is arranged on the semiconductor body (1).

10. The semiconductor component as claimed in claim 9,
wherein
the curvature element (600, 800, 8) is a metal-containing stress layer (800, 8) applied to the semiconductor body (1).

11. The semiconductor component as claimed in claim 1,
wherein
the semiconductor body (1) has an active zone (2) intended for the generation of radiation.

12. The semiconductor component as claimed in claim 11, wherein the semiconductor component is a surface emitting semiconductor component.

13. The semiconductor component as claimed in claim 11,
wherein
the semiconductor component is intended for the generation of laser radiation (13) by means of an external resonator and it is intended to arrange an external mirror (1) for the external resonator downstream of the active zone (2).

14. The semiconductor component as claimed in claim 13,
wherein
the external mirror (11) is embodied in planar fashion.

15. The semiconductor component as claimed in one of claim 11,
wherein
the active zone (2) for the generation of radiation is optically pumped by means of at least one pump radiation source (120).

16. The semiconductor component as claimed in claim 15,
wherein
the pump radiation source (120) and the semiconductor body (1) are monolithically integrated on a common growth substrate.

17. The semiconductor component as claimed in claim 1, wherein
the external resonator includes a nonlinear optical element (16) for frequency conversion of the radiation (13) generated in the active zone.

18. A method for producing a semiconductor component having a curved semiconductor body, comprising the steps of:
a) providing a semiconductor body (1, 100),
b) curving the semiconductor body, and
c) completing the semiconductor component.

19. The method as claimed in claim 18, wherein step a) includes arranging the semiconductor body (1, 100) on a carrier (4, 400).

20. The method as claimed in claim 18,
wherein
the carrier (4, 400) comprises the growth substrate on which the semiconductor body (1, 100) was grown epitaxially.

21. The method as claimed in claim 19,
wherein
a window (5) is formed in the carrier prior to step b).

22. The method as claimed in claim 21,
wherein
the window extends from that side of the carrier (4, 400) which is remote from the semiconductor body (1, 100) as far as to the semiconductor body.

23. The method as claimed in claim 18,
wherein
a stress layer (8, 800) is applied to the semiconductor body (1, 100) as a curvature element, which stress layer curves the semiconductor body, in particular in a region arranged downstream of the window in the vertical direction, by way of compressive stress or tensile stress induced by means of the stress layer.

24. The method as claimed in claim 23,
wherein
the stress layer (8, 800) contains a metal or an alloy.

25. The method as claimed in claim 23,
wherein
the stress layer (8, 800) is sputtered or vapor-deposited onto the semiconductor body (1, 100).

26. The method as claimed in claim 23, wherein step a) includes arranging the semiconductor body (1, 100) on a carrier (4, 400); and
wherein the stress layer (8, 800) is applied to the opposite side of the semiconductor body (1, 100) from the carrier (4, 400).

27. The method as claimed in claim 23,
wherein
the curvature induced by the stress layer (8, 800) is mechanically stabilized by means of a stabilization layer (9, 900) applied to the stress layer.

28. The method as claimed in claim 27,
wherein
the stabilization layer (9, 900) is applied galvanically.

29. The method as claimed in claim 18,
wherein
a shaping element (600) is arranged downstream of the semiconductor body (1, 100) as a curvature element, which has a region which is shaped in accordance with the desired curvature of the semiconductor body and onto which the semiconductor body presses itself or onto which the semiconductor body is pressed in particular in a region that overlaps the window (5).

30. The method as claimed in claim 18,
wherein
a plurality of semiconductor components can be produced simultaneously in the wafer assembly (100, 400).

31. The method as claimed in claim 18,
wherein
the method produces a semiconductor component having a semiconductor body (1), the semiconductor body comprising a curved mirror (3), which is monolithically integrated in the semiconductor body.
